(19) United States
(12) Patent Application Publication
(10) Pub. No.: US 2026/0282481 A1
(43) Pub. Date: Sep. 17, 2026

(54) HIGH RESISTANCE STRUCTURES AND METHODS

(71) Applicant: Taiwan Semiconductor Manufacturing Company, Ltd., Hsinchu (TW)

(72) Inventors: Po-Hsien Wu, Tainan City (TW); I-I Cheng, Tainan City (TW); Li-Yi Chen, Tainan City (TW)

(73) Assignee: Taiwan Semiconductor Manufacturing Company, Ltd., Hsinchu (TW)

(21) Appl. No.: 19/080,397

(22) Filed: Mar. 14, 2025

(51) Int. Cl. H01L 21/28; H10D 64/01; H10D 64/27; H10D 64/66

(52) U.S. Cl. CPC H10D 64/01324; H10D 64/017; H10D 64/518; H10D 64/666

(57) ABSTRACT

High resistance structures and methods for making such structures are provided. A method includes performing a formation process to form a first sacrificial structure over a first region of a substrate; and replacing the first sacrificial structure with a high resistance structure.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography and etching processes to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise within each of the processes that are used, and these additional problems should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a layout view of a semiconductor structure in accordance with embodiments herein;

FIG. 2 is an X-cut cross-sectional view taken along line 2-2 in FIG. 1 in accordance with embodiments herein;

FIG. 3 is an X-cut cross-sectional view taken along line 3-3 in FIG. 1 in accordance with embodiments herein;

FIG. 4 is an X-cut cross-sectional view along line 3-3 in FIG. 1 in accordance with embodiments herein;

FIG. 5 is an X-cut cross-sectional view of the structures of FIG. 3 in accordance with embodiments herein;

FIG. 6 is a flow chart illustrating a method for forming semiconductor structures in accordance with embodiments herein;

FIGS. 7-11 illustrate cross-sectional views of intermediate processing stages of the method of FIG. 6 for fabricating a semiconductor structure, according to certain embodiments;

FIGS. 12-15 illustrate cross-sectional views of intermediate processing stages of the method of FIG. 6 for fabricating a semiconductor structure, according to certain embodiments;

FIGS. 16-19 illustrate cross-sectional views of intermediate processing stages of the method of FIG. 6 for fabricating a semiconductor structure, according to certain embodiments; and

FIGS. 20-23 illustrate cross-sectional views of intermediate processing stages of the method of FIG. 6 for fabricating a semiconductor structure, according to certain embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

When a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

In certain embodiments herein, a “material structure” is a structure that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a structure that is formed of a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of a tungsten structure and a structure formed of tungsten is a structure that is at least 50 wt. %, at least 60 wt. %, at least 75 wt. %, at least 90 wt. %, at least 95 wt. %, or at least 99 wt. % of tungsten.

For the sake of brevity, typical techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many typical processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Presented herein are embodiments of semiconductor structures and devices and of methods for fabricating such structures and/or devices. The present disclosure relates more particularly to interconnect structures for integrated circuit devices. Methods described herein may be easily integrated into the current process flow.

More specifically, embodiments herein provide for forming high resistance structures within the typical process flow for forming semiconductor devices. For example, in embodiments herein, gate structures may be formed in certain device regions as high resistance structures. More specifically, sacrificial gate structures may be formed over a substrate and may be replaced in certain device regions with high resistance structures for use in conductive paths and in other device regions with metal gate structures for use in devices.

In advanced technologies, High Resistance (HR) process is needed for voltage divider and impedance matching. During typical processing, an extra titanium nitride (TiN) is formed. The thickness of the high resistance layer must be maintained to provide resistance control, and the layer must be isolated from the device contact.

Embodiments herein avoid the need to form the extra high resistance layer by embedding the formation of the high resistance structure in the gate formation process. In embodiments herein, normal and high resistance gates may coexist in the same chip and be integrated in device domain to save area.

In certain embodiments herein, “high resistance” refers to a resistance of at least 1 K ohm/cm².

As described herein high resistance structures may be formed with a desired resistance through the design of the structure, including through choice of materials used to form different regions of the structure, and to the size of the structure and size of regions therein. Specifically, the height of the high resistance structure and the height of the components therein may be designed and achieved to provide a desired resistance.

The provided high resistance structures may be connected in series, and/or in parallel to provide a conductive path with a desired resistance.

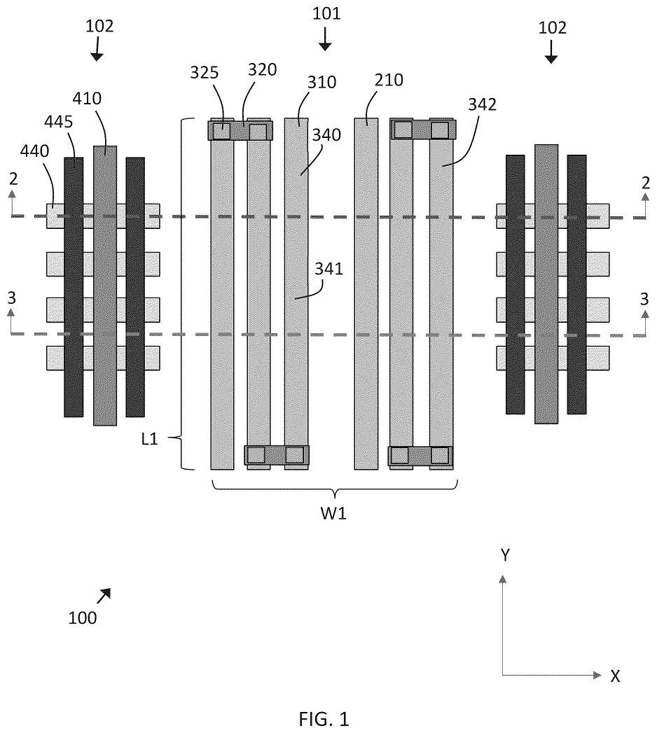

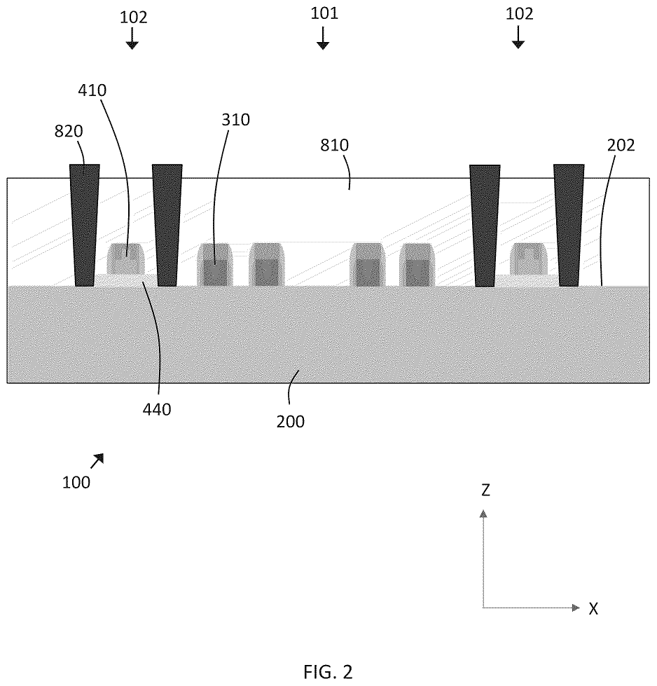

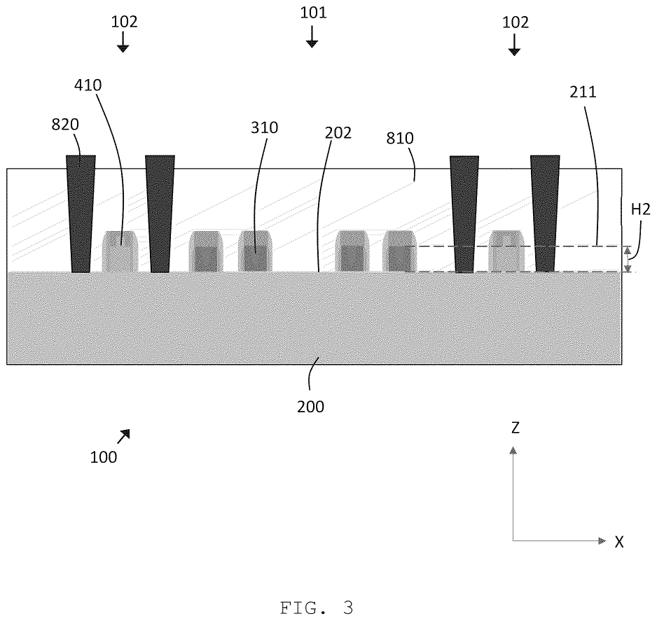

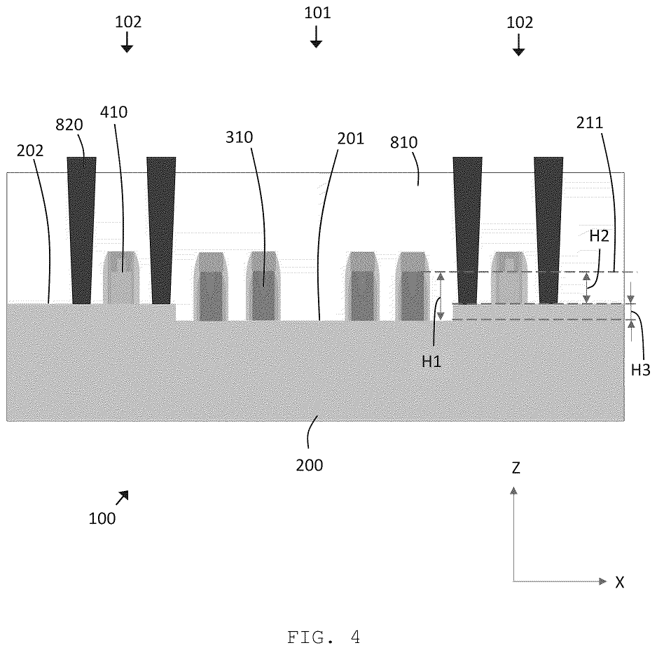

Referring to FIG. 1, a layout view of a semiconductor device or structure 100 is provided. FIG. 2 provides an X-cut cross-sectional view along line 2-2 in FIG. 1. FIG. 3 provides an X-cut cross-sectional view along line 3-3 in FIG. 1. FIG. 4 provides an X-cut cross-sectional view along line 3-3 in FIG. 1 and illustrates an alternative embodiment to FIG. 3.

Cross-referencing FIGS. 1-4, the structure 100 is formed over a substrate 200. As shown, the structure 100 and/or substrate 200 includes a first device region 101 and second device regions 102.

As further shown, isolation features 440, such as shallow trench isolation (STI) features, are formed in the second device regions 102.

As further shown, gate structures 210 are formed in the first device region 101 and the second device regions 102. Specifically, high resistance gate structures 310 are formed in the first device region 101 and metal gate structures 410 are formed in the second device regions 102 via a common gate formation process.

As shown in FIGS. 2-4, a dielectric material such as an interlayer dielectric (ILD) 810 is formed over the gate structures 210. Further contacts 820 are formed through the ILD 810 as desired.

As shown in FIG. 1, the gate structures 210 extend in the Y-direction and are spaced apart from one another in the X-direction. Further, the high resistance gate structures 310 extend in the Y-direction for a length L1, and are spaced apart in the X-direction for a width W1. When designing a structure 100, the length L1 and width W1 may be selected to provide a conductive path 340 with a desired resistance.

High resistance gate structures 210 may be electrically connected by conductive lines 320 and conductive vias 325 to form conductive paths 340. As shown, high resistance gate structures 210 may be connected in series to form conductive paths 341, or in parallel to form conductive paths 342.

As indicated in FIG. 3, the gate structures 310 and 410 may be formed over an upper surface 202 of the substrate 200 that extends across both device region 101 and device region 102. Further, each gate structure 310 and 410 may have an uppermost surface at a plane 211 parallel to the upper surface 202. Thus, each gate structure 310 and 410 may have a vertical height H2 defined as the vertical distance from the upper surface 202 to the plane 211. As used herein, vertical refers to the Z-direction in the Figures.

FIG. 4 illustrates an alternative embodiment. In FIG. 4, the substrate 200 in the first device region 101 is etched to a recessed surface 201. As shown, the recessed surface 201 is located at a vertical height H3 below the upper surface 202. As further shown, the uppermost surfaces of the gate structures 310 and 410 are on plane 211. Therefore, the gate structures 310 are provided with a vertical height H1 equal to the sum of vertical height H2 and vertical height H3, while gate structures 410 have vertical height H2. In this manner, the gate structures 310 may be designed with a vertical height H1 that is independent of the vertical height H2 of the gate structures 410. Thus, the gate structures 310 may be provided with a desired resistance based on vertical height H1 without affecting the formation of gate structures 410.

In certain embodiments, a ratio of height H2 to height H1 is from 1:10 to 1:1.1, including all values and ranges therein, such as at least 1:10, at least 2:10, at least 3:10, at least 4:10, at least 5:10, at least 6:10, at least 7:10, at least 8:10, at least 9:10, or at least 9.5:10; and at most 9.5:10, such as at most 9:10, at most 8:10, at most 7:10, at most 6:10, at most 5:10, at most 4:10, at most 3:10, at most 2:10, or at most 1:10.

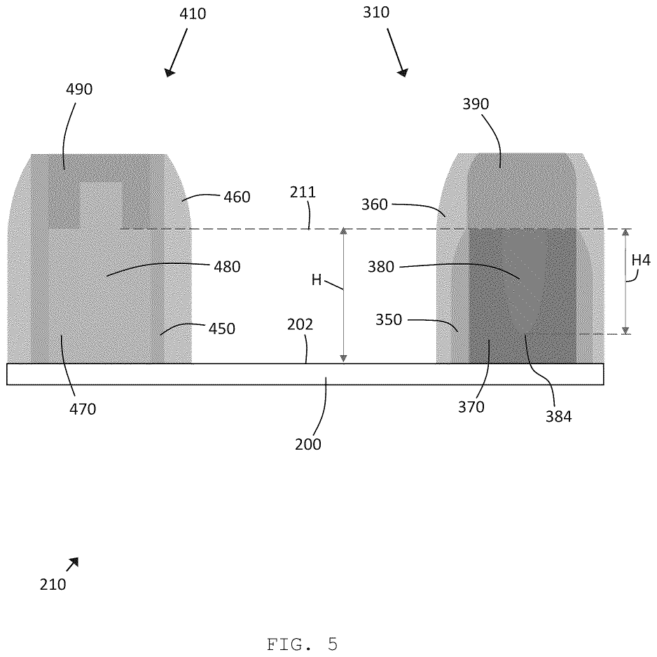

FIG. 5 is a cross-sectional view, similar to FIG. 3, but focused on a gate structure 310 and a gate structure 410 for description thereof.

As shown in FIG. 5, high resistance gate structure 310 includes a core portion or region 380 surrounded laterally by a peripheral portion or region 370. The uppermost surfaces of core region 380 and peripheral region 370 are at plane 211. The core region 380 extends downward from the uppermost surface at plane 211 to a lowest point or surface 384. Thus, the core region 380 has a vertical height H4 from lowest point 384 to the uppermost surface at plane 211. The peripheral region 370 (and gate structure 310) has a vertical height H extending from upper surface 202 (or in other embodiments from recessed surface 201) of substrate 200 to the uppermost surface of the peripheral region 370 at plane 211. Height H4 of core region 380 may be designed and achieved to provide a desired resistance of the high resistance gate structure 310. As noted above, height H may be increased by recessing the substrate 200 to a recessed surface 201. In this manner, the height H of the peripheral region 370 and gate structure 310 may be designed and achieved to provide a desired resistance of the high resistance gate structure 310.

In certain embodiments, a ratio of height H4 to height H is from 1:10 to 1:1.1, including all values and ranges therein, such as at least 1:10, at least 2:10, at least 3:10, at least 4:10, at least 5:10, at least 6:10, at least 7:10, at least 8:10, at least 9:10, or at least 9.5:10; and at most 9.5:10, such as at most 9:10, at most 8:10, at most 7:10, at most 6:10, at most 5:10, at most 4:10, at most 3:10, at most 2:10, or at most 1:10.

As shown in FIG. 5, the peripheral region 370 is surrounded laterally by a sidewall spacer 350. Further, an etch stop layer 360 surrounds the sidewall spacer 350. As further shown, a self-aligned contact 390 is formed over the core region 380 and peripheral region 370. An exemplary self-aligned contact 390 is formed from tungsten, or another suitable conductive metal, and may include an adhesion layer, such as a dual layer including titanium and titanium nitride. An interface between the self-aligned contact 390 and the core region 380 and peripheral region 370 may be at the plane 211. In the high resistance gate structure 310, the self-aligned contact 390 may contact the etch stop layer 360 directly. For example, the sidewall spacer 350 may not extend above plane 211.

As shown in FIG. 5, metal gate structure 410 includes a core portion or region 480 surrounded laterally by a peripheral portion or region 470. While the peripheral region 470 may extend upward from the surface 202 of the substrate 200 to the plane 211, the core region 480 may extend above plane 211. As shown, a self-aligned contact 490 is located over the peripheral region 470 and core region 480. As further shown, a sidewall spacer 450 laterally surrounds the peripheral region 470 and self-aligned contact 90. Further, an etch stop layer 460 laterally surrounds the sidewall spacer 450. In gate structure 410, the etch stop layer 460 may not contact the self-aligned contact 490.

Referring to high resistance gate structure 310, in embodiments herein, the core region 380 and peripheral region 370 are formed from different materials. For example, core region 380 may be formed from air, i.e., may be an air gap, from work function metal (WFM), from dielectric material, or from another suitable material provided a desired resistance. Further, the peripheral region 370 may be formed from work function metal (WFM), from dielectric material, or from another suitable material provided a desired resistance. Embodiments for forming a structure 100 with the high resistance gate structure 310 having the desired components are now described.

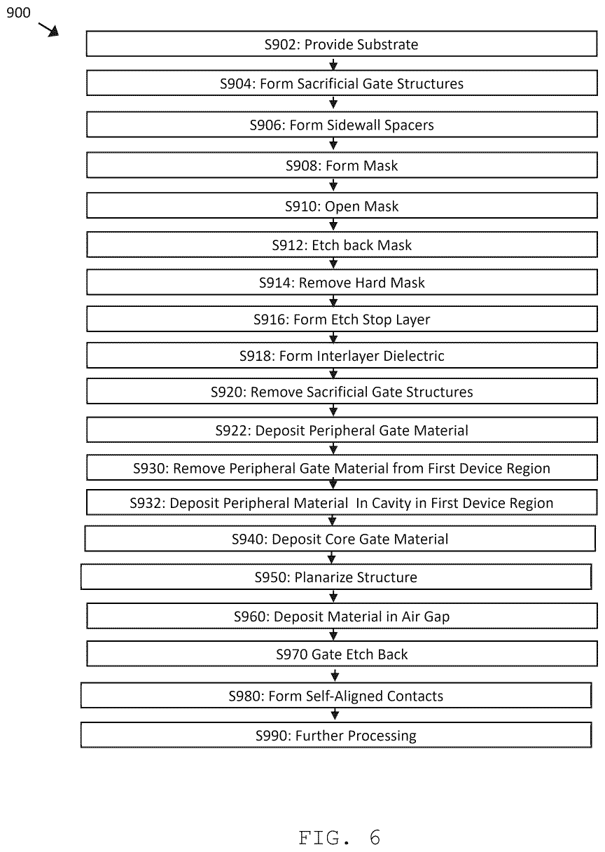

FIG. 6 is a flow chart illustrating a method 900 for fabricating a semiconductor structure, such as structure 100 of FIGS. 1, 2, 3, 4, or 5, according to various aspects of the present disclosure.

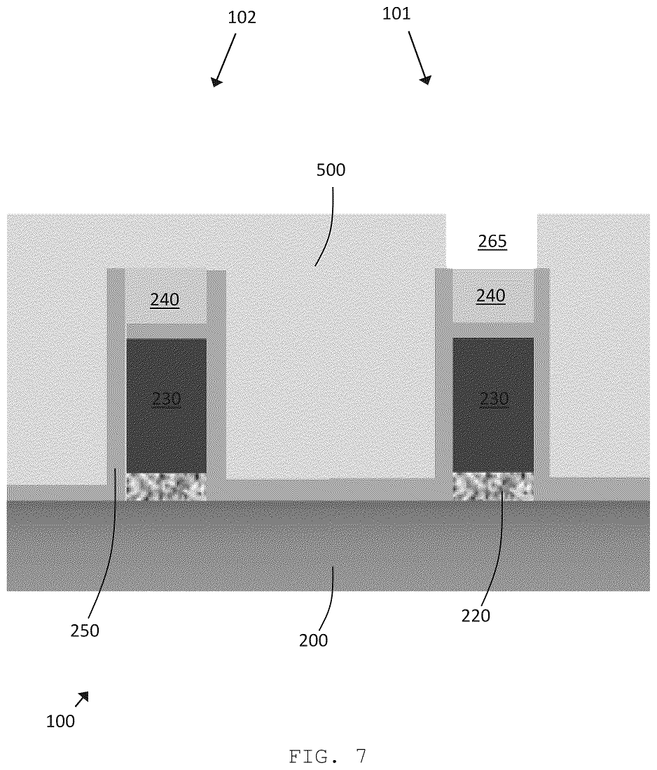

FIG. 6 is described in conjunction with FIGS. 7-23, which illustrate a semiconductor structure or device 100 at various stages of fabrication in accordance with some embodiments of the present disclosure of the method 900. The method 900 is merely an example, and is not intended to limit the present disclosure beyond what is explicitly recited in the claims. Additional steps may be provided before, during, and after method 900, and some of the steps described can be moved, replaced, or eliminated for additional embodiments of method 900. Additional features may be added in the semiconductor device depicted in the Figures and some of the features described below can be replaced, modified, or eliminated in other embodiments of the semiconductor device.

As with other method embodiments and exemplary devices discussed herein, it is understood that parts of the semiconductor structure 100 may be fabricated by typical semiconductor technology process flow, and thus some processes are only briefly described herein. Further, the exemplary semiconductor devices may include various other devices and features, such as other types of devices such as additional transistors, bipolar junction transistors, resistors, capacitors, inductors, diodes, fuses, and/or other logic devices, etc., but is simplified for a better understanding of concepts of the present disclosure. In some embodiments, the exemplary devices include a plurality of semiconductor devices (e.g., transistors), including PFETs, NFETs, etc., which may be interconnected. Moreover, it is noted that the process steps of method 900, including any descriptions given with reference to the Figures, as with the remainder of the method and exemplary figures provided in this disclosure, are merely exemplary and are not intended to be limiting beyond what is specifically recited in the claims that follow.

At operation S902, the method 900 (FIG. 6) provides a substrate 200, as shown in FIG. 7. In some embodiments, the substrate 200 may be a semiconductor substrate such as a silicon (Si) substrate. The substrate 200 may include various layers, including conductive or insulating layers formed on a semiconductor substrate. The substrate 200 may include various doping configurations depending on design requirements as is known in the art. For example, different doping profiles (e.g., p-well, n-well) may be formed on the substrate 200 in regions designed for different device types (e.g., n-type field effect transistors (NFET), p-type field effect transistors (PFET)). The suitable doping may include ion implantation of dopants and/or diffusion processes, such as boron (B) for the p-well and phosphorous (P) for the n-well. In some embodiments, the substrate 200 includes a single crystalline semiconductor layer on at least its surface portion. The substrate 200 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 200 may include a compound semiconductor and/or an alloy semiconductor. In the illustrated embodiment, the substrate 200 is made of crystalline Si.

Still referring to FIG. 7, at operation S904, the method 900 (FIG. 6) may form sacrificial gate structures 230 over the substrate 200. The sacrificial gate structures 230 may include a sacrificial gate dielectric and a sacrificial gate electrode, e.g., poly. Sacrificial gate structure formation may include forming an interfacial layer 220, such as an interfacial oxide layer, over the substrate 200, and a hard mask 240 over the sacrificial gate structure 230. The sacrificial gate structures 230 may be formed by deposition, lithography patterning, and/or etching processes as known in the art.

For both gate-first and gate-last processes, the interfacial layer 220 is formed before sacrificial gate material, e.g., poly, deposition. For gate-last processing, the gate dielectric (gate oxide and high-K dielectric material) is formed after removing the sacrificial gate structures.

The sacrificial gate dielectric is formed over the substrate 200 and may include a dielectric material, such as silicon oxide, silicon oxynitride, silicon nitride, a high dielectric constant (high-k) dielectric material, other suitable dielectric material, or combinations thereof. Exemplary high-k dielectric materials include HfO2, HfSiO, HfSiON, HfTaO, HfSiO, HfZrO, other suitable materials, or combinations thereof. In some embodiments, the sacrificial gate dielectric may be a multilayer structure, for example, including an interfacial layer, and a high-k dielectric material layer formed on the interfacial layer. An exemplary interfacial layer may be a grown silicon oxide layer formed by a thermal process or atomic layer deposition (ALD) process.

The sacrificial gate electrode is formed over the sacrificial gate dielectric. In some embodiments, the sacrificial gate electrode is formed by a polycrystalline silicon (polysilicon) layer.

The hard mask 240 formed over the sacrificial gate structure 230 may include silicon oxide, silicon nitride, silicon oxynitride, silicon carbide, other suitable dielectric material, or combinations thereof. The hard mask may have a multi-layer structure.

Still referring to FIG. 2, at operation S904, the method 900 (FIG. 6) may form sidewall spacers 250 overlying opposite sidewalls of the sacrificial gate structure 230. For example, a first spacer material may be deposited over the sacrificial gate structure 230 and the substrate 200. The first spacer material may be formed by plasma-enhanced chemical vapor deposition (PECVD) and/or other suitable processes. In at least one embodiment, the first spacer material is a dielectric layer including silicon oxide. Thereafter, a second spacer material is deposited over the first spacer material. The second spacer material may be deposited using physical vapor deposition (PVD) (sputtering), chemical vapor deposition (CVD), plasma-enhanced chemical vapor deposition (PECVD), atmospheric pressure chemical vapor deposition (APCVD), low-pressure CVD (LPCVD), high density plasma CVD (HDPCVD), atomic layer CVD (ALCVD), and/or other suitable processes. In at least one embodiment, the second spacer material is a dielectric layer including silicon nitride. Other exemplary compositions for the second spacer material include silicon oxide, silicon carbide, silicon oxynitride, combinations thereof, and/or other suitable materials.

After the formation of the first and second spacer materials over the sacrificial gate structure 230, a patterning process, e.g., blanket dry etching process, may be performed on the first and second spacer materials. For example, the etching process may include an anisotropic etch to partially remove the first and second spacer materials from the substrate 200 in regions where epitaxy features or raised source/drain features will be formed (not shown).

The method 900 (FIG. 6) may continue with forming trenches (not shown) in the substrate 200 at either side of the sacrificial gate structure 230, and forming source/drain features therein (not shown), such as by growing epitaxial material.

Still referring now to FIG. 7, at operation S908, method 900 includes forming a mask 500 over the structure 100. For example, the mask 500 may be photoresist.

Further, at operation S910, method 900 includes opening the mask 500 over the sacrificial gate structures 230 in the first device region 101. As shown, mask openings 265 are formed over the sacrificial gate structures 230 in the first device region 101.

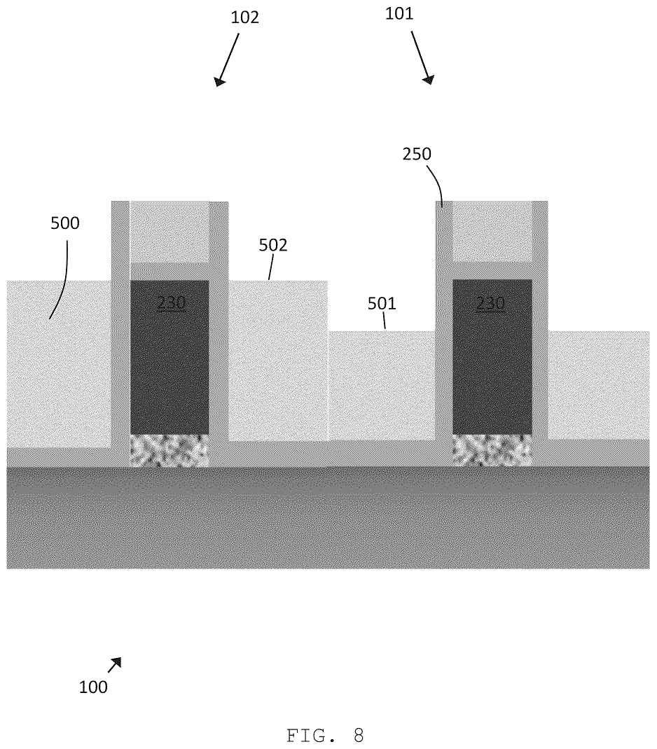

Referring now to FIG. 8, method 900 (FIG. 6) includes, at operation S912, performing a mask etch back to lower the mask 500 to upper surface 501 in device region 101 and to upper surface 502 in device region 102. As shown, upper surface 501 is lower than upper surface 502. Upper surface 501 may be below the upper surface of sacrificial gate structure 230. Further, surface 502 may be at or higher than the upper surface of sacrificial gate structure 230.

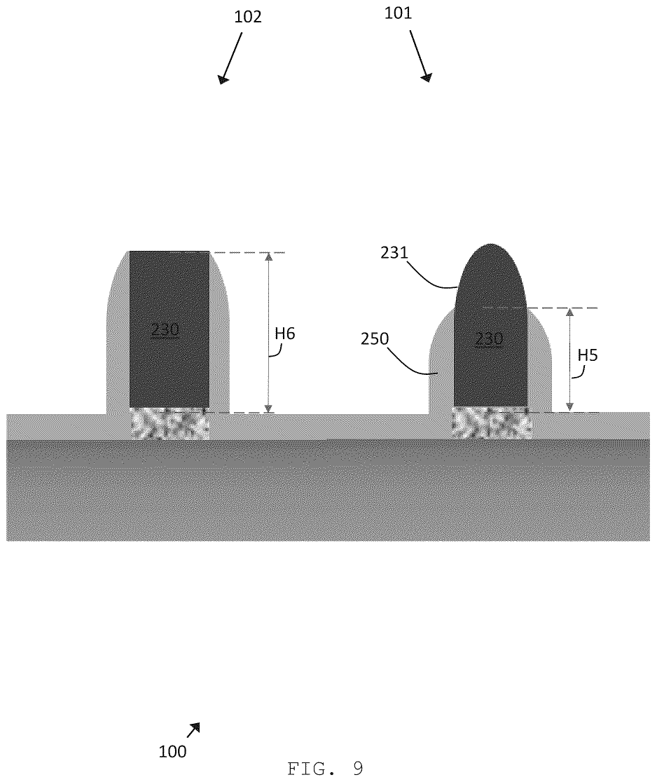

As shown in FIG. 9, method 900 (FIG. 6) includes, at operation S914, performing a hard mask removal process. As shown, due to the previous etch back of mask 500 to surface 501 in device region 101, the hard mask removal etch may remove more of the sidewall spacers 250 in the first device region 101 than in the second device region 102. As a result, the sidewall spacers 250 in the first device region 101 may have a vertical height H5 that is less than the vertical height H6 of sidewall spacers 250 in the second device region 102. For example, a ratio of vertical height H5 to vertical height H6 may be from 0.5:1 to 1:1, including all values and ranges therein, such as at least 0.5:1, at least 0.6:1, at least 0.7:1, at least 0.8:1, at least 0.9:1, or at least 0.95:1; and at most 1:1, at most 0.9:1, at most 0.8:1, at most 0.7:1, at most 0.6:1, or at most 0.55:1. As shown, after the hard mask removal process etches the sidewall spacers 250 in the first device region 101, a portion 231 of the sidewall of the sacrificial gate structure 230 is uncovered, while the side of the sacrificial gate structure 230 in the second device region 102 is still covered by the laterally-surrounding sidewall spacer 250.

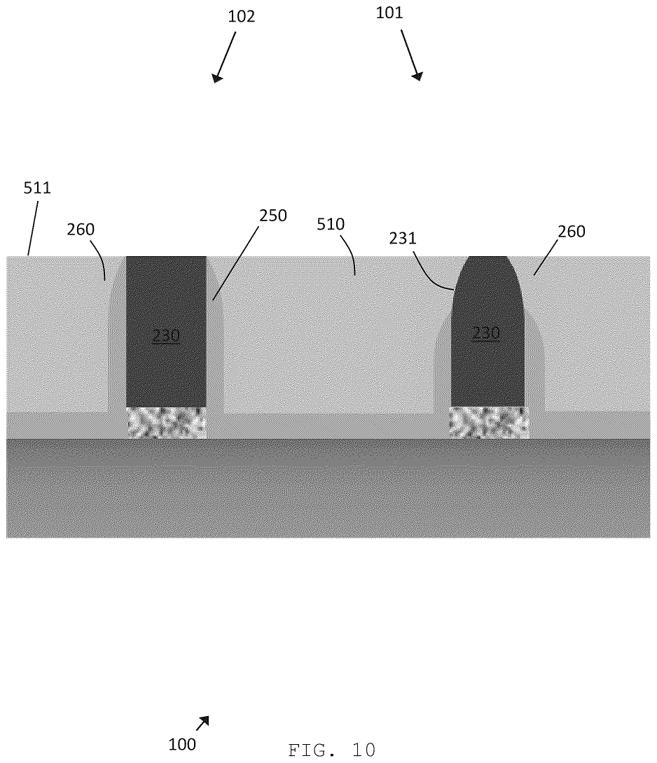

As shown in FIG. 10, at operation S916, method 900 forms an etch stop layer 260 around the sacrificial gate structures 230. In the first device region 101, the etch stop layer 260 contacts and covers the previously-uncovered sidewall portion 231.

Still referring to FIG. 10, at operation S918, method 900 deposits a dielectric material such as an interlayer dielectric (ILD) 510. Further, operation S918 includes planarizing the ILD 510 and structure 100 to an upper surface 511.

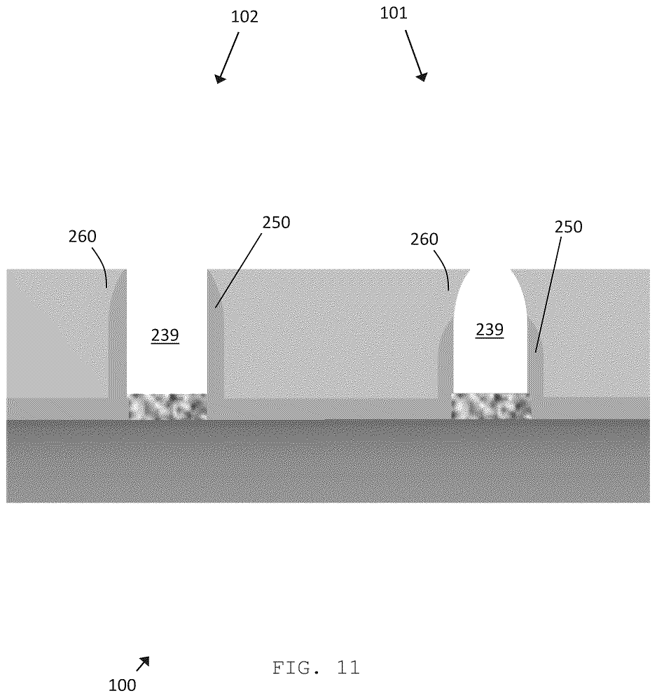

As shown in FIG. 11, method 900 may include, at operation S920, removing the sacrificial gate structures to form gate cavities 239.

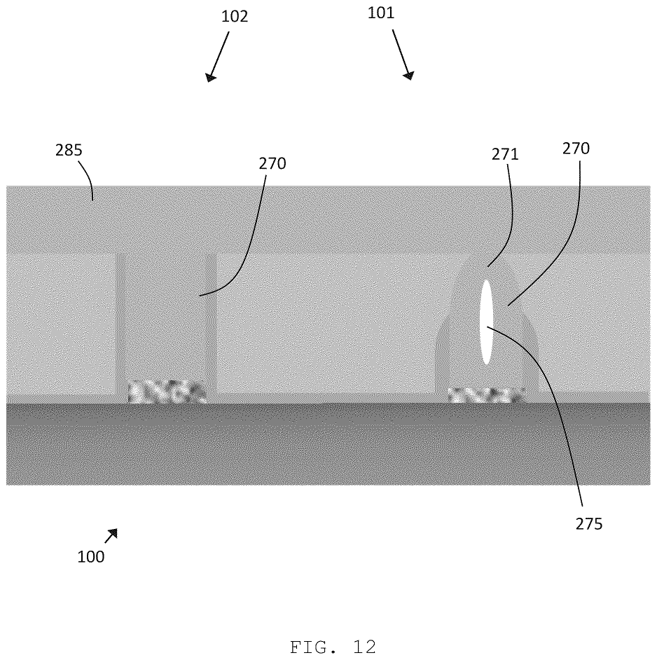

As shown in FIG. 12, method 900 may include, at operation S922, depositing a peripheral gate material 270. For example, the peripheral gate material 270 may be a work function metal (WFM). As shown, the peripheral gate material 270 is conformally deposited to line the sidewalls and bottoms of the cavities 239. The peripheral gate material 270 may be selectively removed from the top surface 511 of the ILD 510.

As shown in FIG. 12, in the first device region 101, the peripheral gate material 270 may merge at an upper location 271 to enclose an air gap 275.

Still referring to FIG. 12, method 900 may include, at operation S940, depositing a core gate material 285. For example, the core gate material 285 may be a metal such as tungsten. As shown, the core gate material 285 fills the remaining cavity 239 in the second device region 102. However, in the first device region 101, the merged peripheral gate material 270 prevents the core gate material 285 from entering the cavity 239 and maintains the sealed air gap 275.

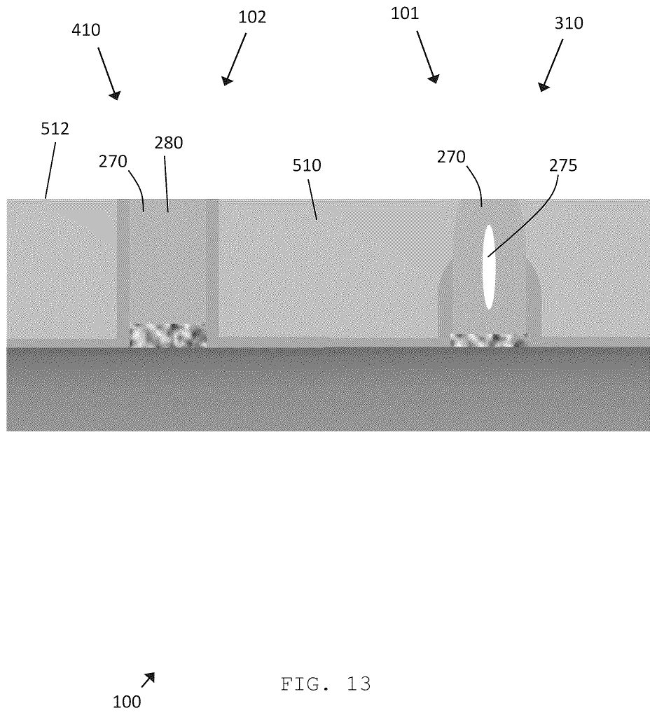

As shown in FIG. 13, method 900 may include, at operation S950, planarizing the structure 100 to an upper surface 512 to remove the overburden portion of the core gate material 285 and form the core portion 280 in the second device region 102. In embodiments using non-self-aligned contact processing, FIG. 13 may illustrate a finished structure before additional dielectric metallization layers may be formed over the structure 100, and contact vias may be formed in contact with the gate structure 310 and/or 410, such as during further processing at operation S990. As shown, a high resistance gate structure 310 including peripheral gate material 270 and air gap 275 is formed in first device region 101 and a gate structure 410 including peripheral gate material 270 and core gate material 280 is formed in second device region 102.

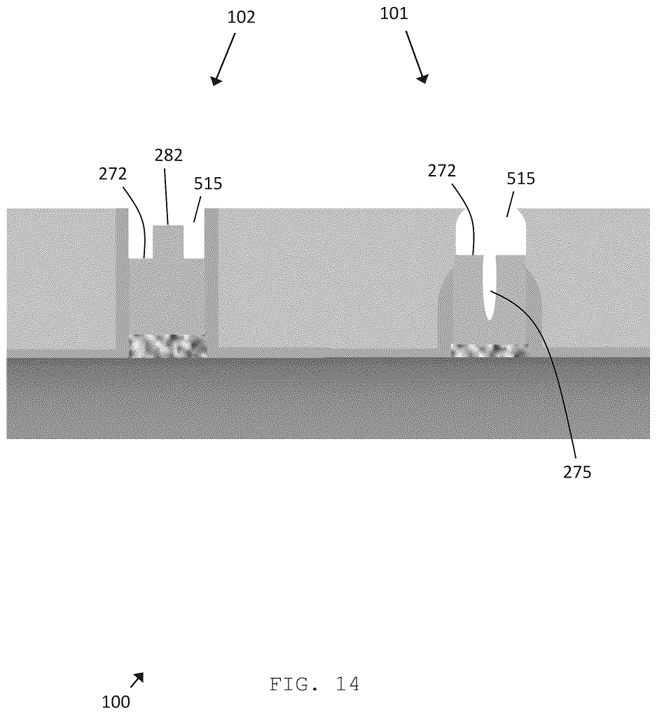

FIG. 14 illustrates operation S970, used in self-aligned contact processing. Specifically, after planarizing the structure 100, method 900 may perform an etch back process at operation S970. As shown, the etch back process may recess the peripheral gate material 270 to a recessed surface 272, and may etch back the core gate material 280 to a recessed surface 282. As a result, recesses 515 are formed. In certain embodiments, etching back the peripheral gate material 270 to the recessed surface 272 includes opening the air gap 275 in first device region 101.

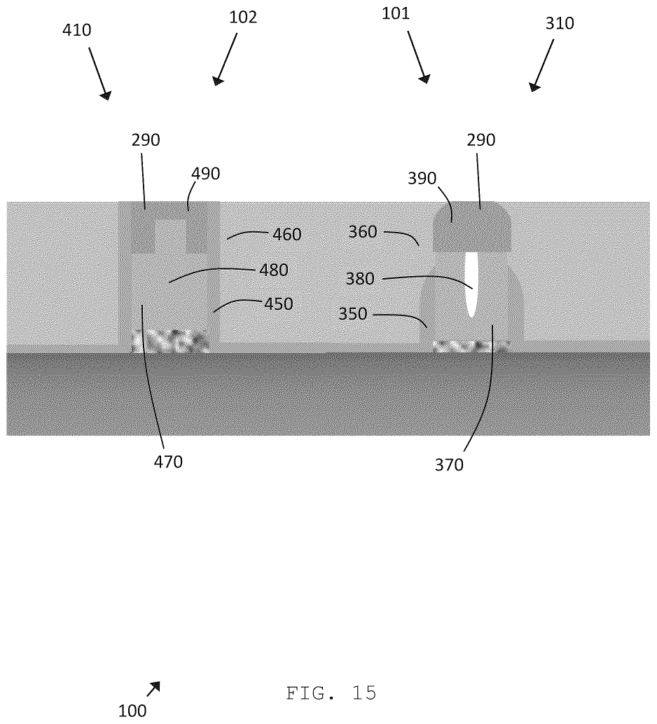

As shown in FIG. 15, method 900 further includes, at operation S980, forming self-aligned contacts 290 in the recesses 515 over the peripheral gate material 270 and over the core gate material 280 or air gap 275.

As a result, a high resistance gate structure 310 is formed in the first device region 101. As shown, the self-aligned contact 290 encloses or encapsulates the air gap 275 as the core region 380 of the high resistance gate structure 310. Further, the peripheral gate material 270 forms the peripheral region 370 of the high resistance gate structure 310. Use of an air gap 275 as the core region 380 may save material and eliminate the for an extra mask process that may be needed to form the core region 380 as a deposited material.

In the gate structure 410 in the second device region 102, the core gate material 280 forms the core region 480, and the peripheral gate material 270 forms the peripheral region 470.

After forming the high resistance gate structure 310 and gate structure 410 in FIG. 15, the method may proceed with further processing at operation S990.

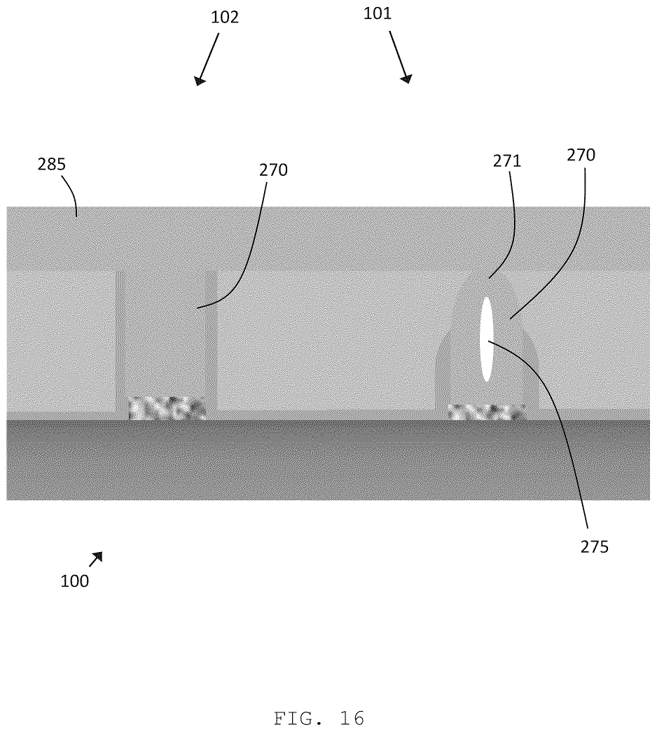

While FIGS. 12-15 illustrate operations for forming the high resistance gate structure 310 with a core region 380 formed from air and a peripheral region 370 formed from work function metal, other embodiments are contemplated. For example, FIGS. 16-19 illustrate another embodiment.

In FIG. 16, operation S922 has deposited a peripheral gate material 270, such as a work function metal (WFM), on the sidewalls and bottoms of the cavities 239, and, in first device region 101, the peripheral gate material 270 has merge at an upper location 271 to enclose an air gap 275. Further, operation S940 has deposited core gate material 285, such as a metal like tungsten, filling the remaining cavity 239 in the second device region 102 while lying over the merged peripheral gate material 270 in the first device region 101.

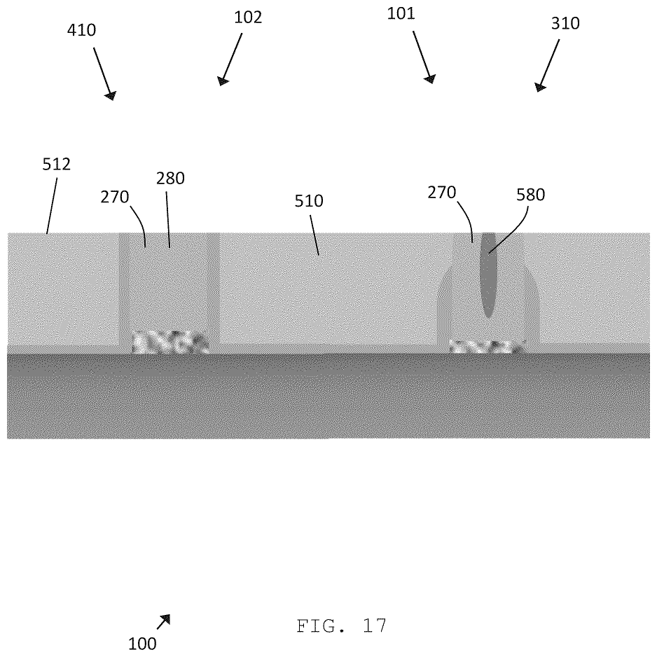

Referring to FIG. 17, method 900 may continue at operation S950, with planarizing the structure 100 to an upper surface 512 to remove the overburden portion of the core gate material 285 and form the core portion 280 in the second device region 102.

Still referring to FIG. 17, method 900 may include, at operation S960, depositing a material 580 in the opened air gap 275 to form a core portion 580. In the embodiment of FIGS. 16-19, the material 580 may be a dielectric material. In certain embodiments, the dielectric material 580 may be silicon oxide, silicon nitride, may include carbon, and may be a low-K dielectric or a high-K dielectric. Any suitable dielectric may be used, and the dielectric material may be selected to provide the high resistance gate structure with a desired resistance. Operation S960 may include masking the second device region 102 while forming the dielectric core portion 580 in the first device region 101.

In embodiments using non-self-aligned contact processing, FIG. 17 may illustrate a finished structure before additional dielectric metallization layers may be formed over the structure 100, and contact vias may be formed in contact with the gate structure 310 and/or 410, such as during further processing at operation S990. As shown, a high resistance gate structure 310 is formed including peripheral gate material 270 as the peripheral region and a dielectric 580 as the core region in first device region 101 and a gate structure 410 including peripheral gate material 270 and core gate material 280 is formed in second device region 102.

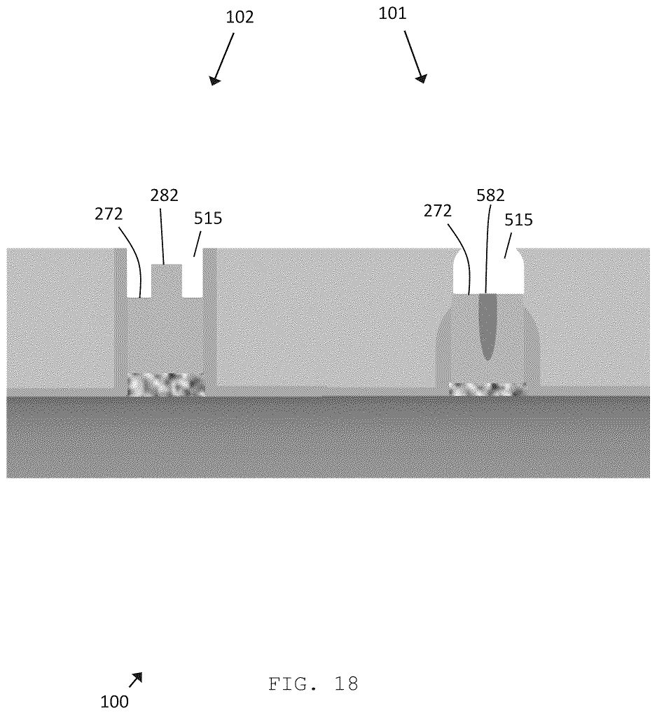

FIG. 18 illustrates operation S970, used in self-aligned contact processing. Specifically, after planarizing the structure 100, method 900 may perform an etch back process at operation S970. As shown, the etch back process may recess the peripheral gate material 270 to a recessed surface 272, may etch back the core gate material 280 to a recessed surface 282, and may etch back the dielectric core material 580 to a recessed surface 582. As a result, recesses 515 are formed.

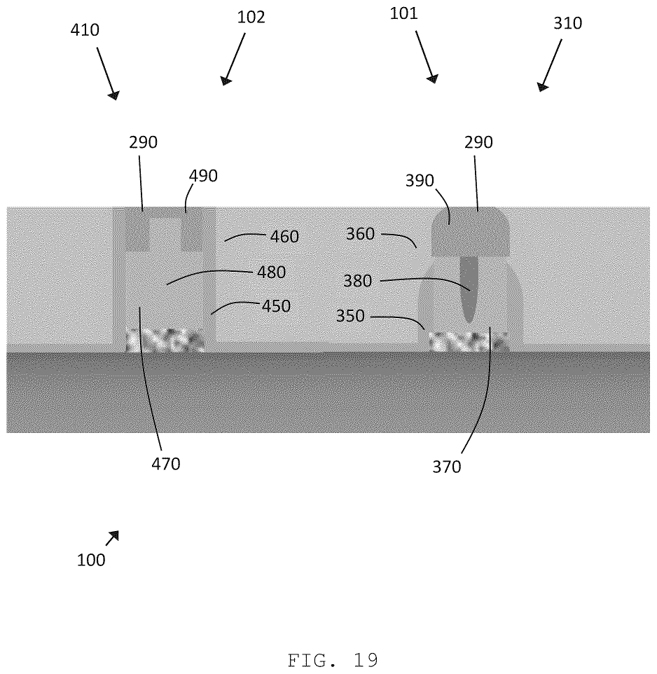

As shown in FIG. 19, method 900 further includes, at operation S980, forming self-aligned contacts 290 in the recesses 515 over the peripheral gate material 270 and over the core gate material 280 or dielectric core material 580.

As a result, a high resistance gate structure 310 is formed in the first device region 101. As shown, the self-aligned contact 290 encloses or encapsulates the dielectric core material as the core region 380 of the high resistance gate structure 310. Further, the peripheral gate material 270 forms the peripheral region 370 of the high resistance gate structure 310.

In the gate structure 410 in the second device region 102, the core gate material 280 forms the core region 480, and the peripheral gate material 270 forms the peripheral region 470.

After forming the high resistance gate structure 310 and gate structure 410 in FIG. 19, the method may proceed with further processing at operation S990.

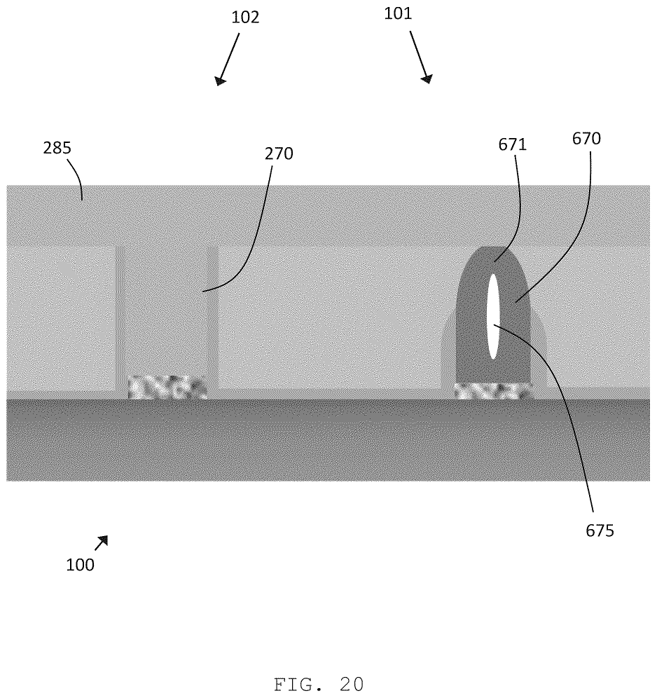

While FIGS. 16-19 illustrate operations for forming the high resistance gate structure 310 with a core region 380 formed from dielectric material and a peripheral region 370 formed from work function metal, other embodiments are contemplated. For example, FIGS. 20-23 illustrate another embodiment.

In FIG. 20, operation S922 has deposited a peripheral gate material 270, such as a work function metal (WFM), on the sidewalls and bottoms of the cavities 239.

In the embodiment of FIG. 20, method 900 continues at operation S930, with removing the peripheral gate material 270 from the first device region 101. For example, operation S930 may include masking the second device region 102 and performing a work function metal removal etch.

Further, in the embodiment of FIG. 20, method 900 includes, at operation S932, depositing a dielectric material 670 in the cavity 239 in the first device region 101. For example, while the second device region 102 is masked, a deposition process may be performed to conformally deposit the dielectric material 670 in the cavity 239 in the first device region 101. As shown, the dielectric material 670 may merge at an upper location 671 to enclose an air gap 675. In certain embodiments, the dielectric material 670 may be silicon oxide, silicon nitride, may include carbon, and may be a low-K dielectric or a high-K dielectric. Any suitable dielectric may be used, and the dielectric material may be selected to reduce capacitance from gate to gate.

In FIG. 20, operation S940 has deposited core gate material 285, such as a metal like tungsten, filling the remaining cavity 239 in the second device region 102 while lying over the merged dielectric material 670 in the first device region 101.

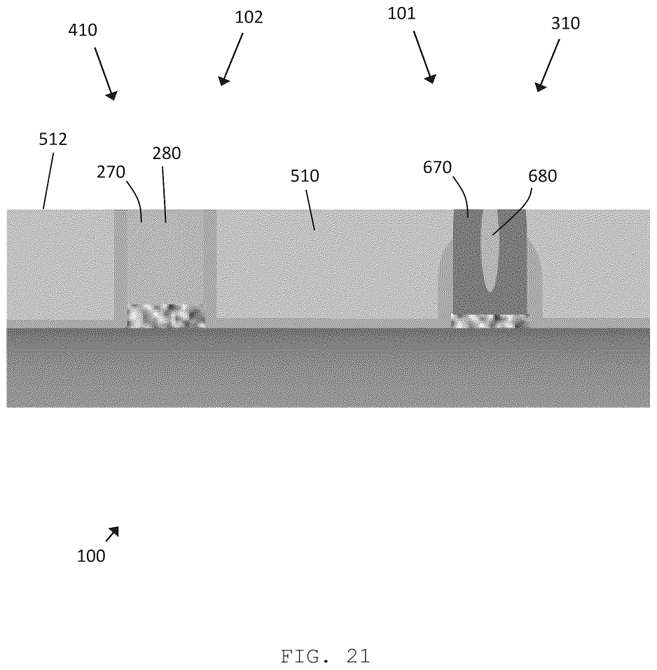

Referring to FIG. 21, method 900 may continue at operation S950, with planarizing the structure 100 to an upper surface 512 to remove the overburden portion of the core gate material 285 and form the core portion 280 in the second device region 102.

Still referring to FIG. 21, method 900 may include, at operation S960, depositing a material in the opened air gap 275 to form a core portion 680. In the embodiment of FIGS. 16-19, the material 680 may be a work function metal, and the work function metal may be selected to provide the high resistance gate structure with a desired resistance. Operation S960 may include masking the second device region 102 while forming the work function metal core portion 680 in the first device region 101.

In embodiments using non-self-aligned contact processing, FIG. 21 may illustrate a finished structure before additional dielectric metallization layers may be formed over the structure 100, and contact vias may be formed in contact with the gate structure 310 and/or 410, such as during further processing at operation S990. As shown, a high resistance gate structure 310 is formed including dielectric material 670 as the peripheral region and a work function metal 680 as the core region in first device region 101 and a gate structure 410 including peripheral gate material 270 and core gate material 280 is formed in second device region 102.

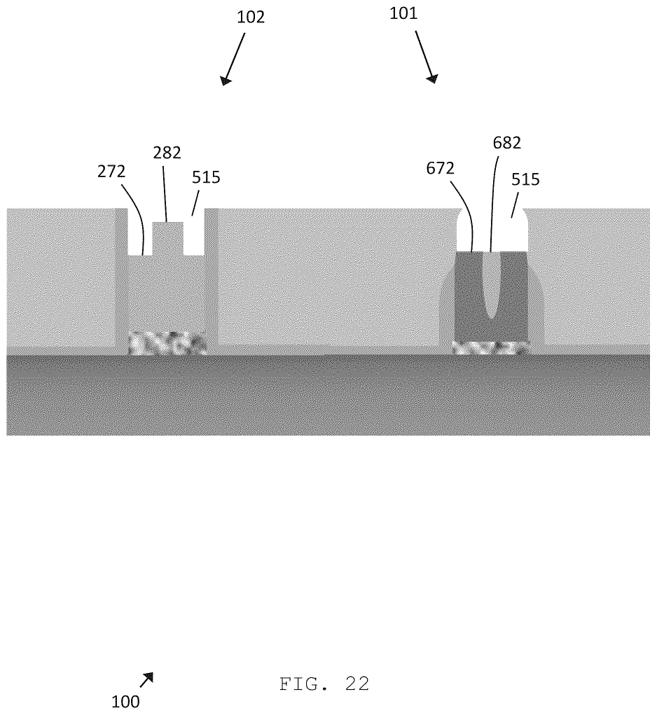

FIG. 22 illustrates operation S970, used in self-aligned contact processing. Specifically, after planarizing the structure 100, method 900 may perform an etch back process at operation S970. As shown, the etch back process may recess the peripheral gate material 270 to a recessed surface 272, may etch back the core gate material 280 to a recessed surface 282, may etch back the dielectric peripheral material 670 to a recessed surface 672, and may etch back the work function metal core material 680 to a recessed surface 682. As a result, recesses 515 are formed.

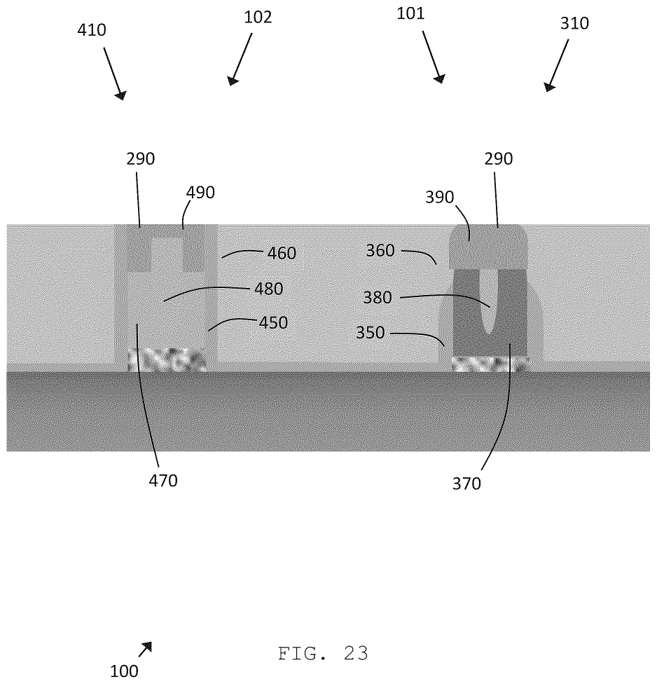

As shown in FIG. 23, method 900 further includes, at operation S980, forming self-aligned contacts 290 in the recesses 515 over the peripheral gate material 270 and core gate material 280 in second device region 102 and over the dielectric peripheral material 670 and work function metal core material 680 in the first device region 101.

As a result, a high resistance gate structure 310 is formed in the first device region 101. As shown, the self-aligned contact 290 encloses or encapsulates the work function metal core material 680 as the core region 380 of the high resistance gate structure 310. Further, the peripheral dielectric material 670 forms the peripheral region 370 of the high resistance gate structure 310.

In the gate structure 410 in the second device region 102, the core gate material 280 forms the core region 480, and the peripheral gate material 270 forms the peripheral region 470.

After forming the high resistance gate structure 310 and gate structure 410 in FIG. 19, the method may proceed with further processing at operation S990.

Thus, several embodiments are illustrated in which the materials of the core region 380 and the peripheral region 370 of the high resistance gate structure 310 are varied while the core region 480 and the peripheral region 470 of the gate structure 410 remain the same. While certain materials have been identified, other materials may be used to form the high resistance gate structure 310 with the desired resistance.

In certain embodiments, a method for designing a high resistance structure 310 is provided. For example, it may be determined that a certain amount of resistance is needed, such as for voltage divider and impedance matching. The method may include determining a length L and width W for a plurality of high resistance gates, such as is shown in FIG. 1. Also, the method may include determining a current path, such as through parallel-arranged and/or serially-arranged high resistance structures. Further, the method may include determining a height H2 for adjacent devices in second device region 102, and determining a height H for the high resistance structures, such as of peripheral regions of the high resistance structures. Also, the method may include determining a height H4 of the core region of the high resistance structures. Moreover, the method may include determining the material for forming the core region and the peripheral region of the high resistance structures. The method includes adjusting of the above determinations to provide the high resistance structures having the desired resistance, and to provide the current path with the desired resistance.

In one embodiment, a method includes performing a formation process to form a first sacrificial structure over a first region of a substrate; and replacing the first sacrificial structure with a high resistance structure.

In certain embodiments of the method, the substrate has an upper surface; and the method further includes recessing the substrate in the first region to a recessed surface before performing the formation process.

In certain embodiments of the method, the formation process further includes forming a second sacrificial structure over a second region of the substrate; and the method further includes forming sidewall spacers, including first sidewall spacers around the first sacrificial structure and second sidewall spacers around the second sacrificial structure; covering the first sidewall spacers, the first sacrificial structure, the second sidewall spacers, and the second sacrificial structure with material; recessing the material to a first recessed surface in the first region and to a second recessed surface in the second region, wherein the first recessed surface is lower than the second recessed surface; performing an etch process, wherein the etch process etches the first sacrificial structure and the first sidewall spacers, such that the first sidewall spacers have a first vertical length and the second sidewall spacers have a second vertical length greater than the first vertical length; forming sidewall etch stop layers, including first sidewall etch stop layers around the first sidewall spacers and second sidewall etch stop layers around the second sidewall spacers; depositing a dielectric over the first region and second region; uncovering the first sacrificial structure and the second sacrificial structure; and removing the first sacrificial structure and the second sacrificial structure to form a first cavity and a second cavity.

In certain embodiments of the method, the formation process further includes forming a second sacrificial structure over a second region of the substrate; the method further includes replacing the second sacrificial structure with a metal structure; and replacing the first sacrificial structure with a high resistance structure and replacing the second sacrificial structure with a metal structure includes lining the first cavity and the second cavity with a work function metal, wherein the work function metal merges at an upper location in the first cavity to form an air gap; removing the work function metal from over the dielectric; depositing a metal over the first region and the second region, wherein the metal fills the second cavity; removing the metal from over the dielectric; recessing the work function metal within the first cavity and the second cavity; and forming conductive contacts, including a first conductive contact in the first cavity and a second conductive in the second cavity, wherein the first conductive contact encloses the air gap.

In certain embodiments of the method, the formation process further includes forming a second sacrificial structure over a second region of the substrate; the method further includes replacing the second sacrificial structure with a metal structure; and replacing the first sacrificial structure with a high resistance structure and replacing the second sacrificial structure with a metal structure includes lining the first cavity and the second cavity with a work function metal, wherein the work function metal merges at an upper location in the first cavity to form a gap; and removing the work function metal from over the dielectric; depositing a metal over the first region and the second region, wherein the metal fills the second cavity; removing the metal from over the dielectric; recessing the work function metal within the first cavity and the second cavity and opening the gap; depositing a dielectric core material in the gap to form a dielectric core; and forming conductive contacts, including a first conductive contact in the first cavity and a second conductive in the second cavity.

In certain embodiments of the method, the formation process further includes forming a second sacrificial structure over a second region of the substrate; the method further includes replacing the second sacrificial structure with a metal structure; and replacing the first sacrificial structure with a high resistance structure and replacing the second sacrificial structure with a metal structure includes lining the first cavity with a dielectric material, wherein the dielectric material merges at an upper location in the first cavity to form a gap; lining the second cavity with a work function metal; removing the work function metal from over the dielectric; depositing a metal over the first region and the second region, wherein the metal fills the second cavity; removing the metal from over the dielectric; recessing the work function metal within the first cavity and the second cavity and opening the gap; depositing a work function metal in the gap to form a work function metal core; and forming conductive contacts, including a first conductive contact in the first cavity and a second conductive in the second cavity.

In another embodiment, a method for fabricating a semiconductor structure includes determining a design for a high resistance structure including a central core region surrounding by a peripheral region; adjusting the design of the high resistance structure to obtain a desired resistance by selecting a first material to form the central core region, wherein the first material is selected from a first plurality of materials having known resistances, and by selected a second material to form the peripheral region, wherein the second material is selected from a second plurality of materials having known resistances; and building the high resistance structure from the first material and the second material, wherein the high resistance structure has the desired resistance.

In certain embodiments of the method, adjusting the design of the high resistance structure to obtain the desired resistance further includes selecting a vertical height of the central core region; and selecting a vertical height of the peripheral region.

In certain embodiments of the method, the first plurality of materials includes air, dielectric, and work function metal.

In certain embodiments of the method, the second plurality of materials includes dielectric and work function metal.

In certain embodiments of the method, building the high resistance structure from the first material and the second material includes: etching a first device region of a substrate to a recessed surface at a desired depth; and forming the peripheral region and the central core region of the high resistance structure over the recessed surface, wherein a vertical height of the peripheral region extends from an uppermost surface of the peripheral region to the recessed surface of the substrate.

In certain embodiments of the method, the high resistance structure is a high resistance gate structure; a gate structure building process includes building the high resistance gate structure from the first material and the second material in a first device region of a substrate; and the gate structure building process further includes building a second gate structure in a second device region of the substrate, wherein the second gate structure includes a peripheral portion and a core portion, and wherein an uppermost surface of the peripheral portion and an uppermost surface of the peripheral region are formed in a same plane parallel to the substrate.

In certain embodiments of the method, the peripheral portion and the peripheral region are formed by depositing a same material across the first device region and the second device region.

In certain embodiments of the method, building the high resistance structure from the first material and the second material includes etching the first device region of the substrate to a recessed surface at a desired depth; and a vertical height of the peripheral region extends from the uppermost surface of the peripheral region to the recessed surface of the substrate.

In another embodiment, a semiconductor structure includes a high resistance gate structure, wherein the high resistance gate structure includes a high resistance core region surrounded by a high resistance peripheral region; and a conductive path electrically connected to the high resistance gate structure.

In certain embodiments, the semiconductor structure further includes a contact overlying the high resistance gate structure, the contact is directly electrically connected to the high resistance core region and is directly electrically connected to the high resistance peripheral region.

In certain embodiments of the semiconductor structure, the high resistance core region includes air, and the high resistance peripheral region includes work function metal.

In certain embodiments of the semiconductor structure, the high resistance core region includes dielectric material, and the high resistance peripheral region includes work function metal.

In certain embodiments of the semiconductor structure, the high resistance core region includes work function metal, and the high resistance peripheral region includes dielectric material.

In certain embodiments, the semiconductor structure further includes a substrate having a first region with a recessed surface at a first plane and a second region with an upper surface at a second plane above the first plane, wherein the high resistance gate structure is located over the recessed surface in the first region; and a metal gate structure located over the upper surface in the second region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
performing a formation process to form a first sacrificial structure over a first region of a substrate; and
replacing the first sacrificial structure with a high resistance structure.

2. The method of claim 1, wherein:
the substrate has an upper surface; and
the method further comprises recessing the substrate in the first region to a recessed surface before performing the formation process.

3. The method of claim 1, wherein the formation process further includes forming a second sacrificial structure over a second region of the substrate; and the method further comprises:
forming sidewall spacers, including first sidewall spacers around the first sacrificial structure and second sidewall spacers around the second sacrificial structure;
covering the first sidewall spacers, the first sacrificial structure, the second sidewall spacers, and the second sacrificial structure with material;
recessing the material to a first recessed surface in the first region and to a second recessed surface in the second region, wherein the first recessed surface is lower than the second recessed surface;
performing an etch process, wherein the etch process etches the first sacrificial structure and the first sidewall spacers, such that the first sidewall spacers have a first vertical length and the second sidewall spacers have a second vertical length greater than the first vertical length;
forming sidewall etch stop layers, including first sidewall etch stop layers around the first sidewall spacers and second sidewall etch stop layers around the second sidewall spacers;
depositing a dielectric over the first region and second region;
uncovering the first sacrificial structure and the second sacrificial structure; and
removing the first sacrificial structure and the second sacrificial structure to form a first cavity and a second cavity.

4. The method of claim 3, wherein replacing the first sacrificial structure with a high resistance structure and replacing the second sacrificial structure with a metal structure comprises:
lining the first cavity and the second cavity with a work function metal, wherein the work function metal merges at an upper location in the first cavity to form an air gap;
removing the work function metal from over the dielectric;
depositing a metal over the first region and the second region, wherein the metal fills the second cavity;
removing the metal from over the dielectric;
recessing the work function metal within the first cavity and the second cavity; and
forming conductive contacts, including a first conductive contact in the first cavity and a second conductive in the second cavity, wherein the first conductive contact encloses the air gap.

5. The method of claim 3, wherein replacing the first sacrificial structure with a high resistance structure and replacing the second sacrificial structure with a metal structure comprises:
lining the first cavity and the second cavity with a work function metal, wherein the work function metal merges at an upper location in the first cavity to form a gap;
removing the work function metal from over the dielectric;
depositing a metal over the first region and the second region, wherein the metal fills the second cavity;
removing the metal from over the dielectric;
recessing the work function metal within the first cavity and the second cavity and opening the gap;
depositing a dielectric core material in the gap to form a dielectric core; and
forming conductive contacts, including a first conductive contact in the first cavity and a second conductive in the second cavity.

6. The method of claim 3, wherein replacing the first sacrificial structure with a high resistance structure and replacing the second sacrificial structure with a metal structure comprises:
lining the first cavity with a dielectric material, wherein the dielectric material merges at an upper location in the first cavity to form a gap;
lining the second cavity with a work function metal;
removing the work function metal from over the dielectric;
depositing a metal over the first region and the second region, wherein the metal fills the second cavity;
removing the metal from over the dielectric;
recessing the work function metal within the first cavity and the second cavity and opening the gap;
depositing a work function metal in the gap to form a work function metal core; and
forming conductive contacts, including a first conductive contact in the first cavity and a second conductive in the second cavity.

7. A method for fabricating a semiconductor structure comprising:
determining a design for a high resistance gate structure comprising a central core region surrounding by a peripheral region;
adjusting the design of the high resistance gate structure to obtain a desired resistance by selecting a first material to form the central core region, wherein the first material is selected from a first plurality of materials having known resistances, and by selected a second material to form the peripheral region, wherein the second material is selected from a second plurality of materials having known resistances; and
building the high resistance gate structure from the first material and the second material, wherein the high resistance gate structure has the desired resistance.

8. The method of claim 7, wherein adjusting the design of the high resistance gate structure to obtain the desired resistance further comprises:
selecting a vertical height of the central core region; and
selecting a vertical height of the peripheral region.

9. The method of claim 7, wherein the first plurality of materials includes air, dielectric, and work function metal.

10. The method of claim 9, wherein the second plurality of materials includes dielectric and work function metal.

11. The method of claim 7, wherein building the high resistance gate structure from the first material and the second material comprises:
etching a first device region of a substrate to a recessed surface at a desired depth; and
forming the peripheral region and the central core region of the high resistance gate structure over the recessed surface,
wherein a vertical height of the peripheral region extends from an uppermost surface of the peripheral region to the recessed surface of the substrate.

12. The method of claim 7, wherein:
the high resistance gate structure is a high resistance gate structure;
a gate structure building process includes building the high resistance gate structure from the first material and the second material in a first device region of a substrate; and
the gate structure building process further includes building a second gate structure in a second device region of the substrate, wherein the second gate structure comprises a peripheral portion and a core portion, and
wherein an uppermost surface of the peripheral portion and an uppermost surface of the peripheral region are formed in a same plane parallel to the substrate.

13. The method of claim 12, wherein the peripheral portion and the peripheral region are formed by depositing a same material across the first device region and the second device region.

14. The method of claim 12, wherein:
building the high resistance gate structure from the first material and the second material comprises etching the first device region of the substrate to a recessed surface at a desired depth; and
a vertical height of the peripheral region extends from the uppermost surface of the peripheral region to the recessed surface of the substrate.

15. A semiconductor structure comprising:
a high resistance gate structure, wherein the high resistance gate structure includes a high resistance core region surrounded by a high resistance peripheral region; and
a conductive path electrically connected to the high resistance gate structure.

16. The semiconductor structure of claim 15, further comprising a contact overlying the high resistance gate structure, wherein the contact is directly electrically connected to the high resistance core region and is directly electrically connected to the high resistance peripheral region.

17. The semiconductor structure of claim 15, wherein the high resistance core region comprises air, and wherein the high resistance peripheral region comprises work function metal.

18. The semiconductor structure of claim 15, wherein the high resistance core region comprises dielectric material, and wherein the high resistance peripheral region comprises work function metal.

19. The semiconductor structure of claim 15, wherein the high resistance core region comprises work function metal, and wherein the high resistance peripheral region comprises dielectric material.

20. The semiconductor structure of claim 15, further comprising:
a substrate having a first region with a recessed surface at a first plane and a second region with an upper surface at a second plane above the first plane, wherein the high resistance gate structure is located over the recessed surface in the first region; and
a metal gate structure located over the upper surface in the second region.
